(19) United States
(12) Patent Application Publication
(10) Pub. No.: US 2026/0044447 A1
(43) Pub. Date: Feb. 12, 2026

(54) STORAGE DEVICE FOR READING DATA AND METHOD OF OPERATING THE SAME

(71) Applicant: SK hynix Inc., Gyeonggi-do (KR)

(72) Inventor: Kyung Bum KIM, Gyeonggi-do (KR)

(21) Appl. No.: 19/063,331

(22) Filed: Feb. 26, 2025

(30) Foreign Application Priority Data
Aug. 9, 2024 (KR) 10-2024-0107004

(51) Int. Cl. G06F 12/02; G11C 16/04; G11C 16/08; G11C 16/26

(52) U.S. Cl. CPC G06F 12/0246; G11C 16/0483; G11C 16/08; G11C 16/26

(57) ABSTRACT

Provided herein may be a storage device and a method of operating the same. The storage device may include a memory device including a plurality of memory blocks connected to a plurality of word lines, respectively, and configured to perform a read operation on a target memory block among the plurality of memory blocks, and a memory controller configured to control the memory device to adjust a pass voltage depending on whether a number of read operations performed on the target memory block reaches a first number, and apply the adjusted pass voltage to at least one unselected word line among the plurality of word lines.

### CROSS-REFERENCE TO RELATED APPLICATION

The present application claims priority under 35 U.S.C. § 119(a) to Korean patent application number 10-2024-0107004 filed on Aug. 9, 2024, the entire disclosure of which is incorporated by reference herein.

### BACKGROUND

### 1. Technical Field

Various embodiments of the present disclosure generally relate to a semiconductor device, and more particularly to a storage device for reading data and a method of operating the storage device.

### 2. Related Art

A storage device may store data under the control of a host device. The storage device may include a memory device in which data is stored and a memory controller which controls the memory device.

The storage device may perform a read reclaim operation to improve reliability. The read reclaim operation may be an operation of moving, to another memory area, data in a target memory area having a high probability of read fall occurrence.

However, when the read reclaim operation frequently occurs, the performance of the storage device may be deteriorated. Therefore, there is required a scheme capable of improving the reliability of the storage device while increasing the initial performance of the storage device.

### SUMMARY

Various embodiments of the present disclosure are directed to a storage device and a method of operating the storage device, which can improve reliability while enhancing initial performance by delaying a time point at which a read reclaim operation is performed.

An embodiment of the present disclosure may provide for a storage device. The storage device may include a memory device including a plurality of memory blocks connected to a plurality of word lines, respectively, and configured to perform a read operation on a target memory block among the plurality of memory blocks, and a memory controller configured to control the memory device to adjust a pass voltage depending on whether a number of read operations performed on the target memory block reaches a first number, and apply the adjusted pass voltage to at least one unselected word line among the plurality of word lines.

An embodiment of the present disclosure may provide for a method of operating a storage device, which includes a plurality of memory blocks connected to a plurality of word lines, respectively. The method may include counting a number of read operations performed on a target memory block among the plurality of memory blocks, determining a magnitude of a pass voltage depending on whether the number of read operations reaches a first number, and performing the read operation on the target memory block by applying the pass voltage having the determined magnitude to at least one unselected word line among the plurality of word lines.

An embodiment of the present disclosure may provide for a memory device. The memory device may include a plurality of memory blocks connected to a plurality of word lines, respectively, a voltage generator configured to generate a pass voltage to be applied to at least one unselected word line among the plurality of word lines during a read operation on a target memory block among the plurality of memory blocks, and a control circuit configured to control the voltage generator to adjust the pass voltage depending on whether a number of read operations performed on the target memory block reaches a preset number.

### BRIEF DESCRIPTION OF THE DRAWINGS

FIG. 1 is a diagram illustrating a storage device according to an embodiment of the present disclosure.

FIGS. 2A and 2B are diagrams illustrating a read claim operation according to an embodiment of the present disclosure.

FIG. 3 is a diagram illustrating determining a pass voltage to be applied to an unselected word line according to an embodiment of the present disclosure.

FIG. 4 is a diagram illustrating a pass voltage applied to an unselected word line according to an embodiment of the present disclosure.

FIG. 5 is a diagram illustrating determining a pass voltage to be applied to an unselected word line according to an embodiment of the present disclosure.

FIG. 6 is a diagram illustrating a pass voltage applied to an unselected word line according to an embodiment of the present disclosure.

FIG. 7 is a diagram illustrating a pass voltage applied to an unselected word line according to an embodiment of the present disclosure.

FIG. 8 is a flowchart illustrating a method of operating a storage device according to an embodiment of the present disclosure.

FIG. 9 is a diagram illustrating a memory controller according to an embodiment of the present disclosure.

FIG. 10 is a diagram illustrating a memory device according to an embodiment of the present disclosure.

### DETAILED DESCRIPTION

Specific structural or functional descriptions in the embodiments of the present disclosure introduced in this specification are provided as examples to describe embodiments according to the concept of the present disclosure. The embodiments according to the concept of the present disclosure may be practiced in various forms, and should not be construed as being limited to the embodiments described in this specification.

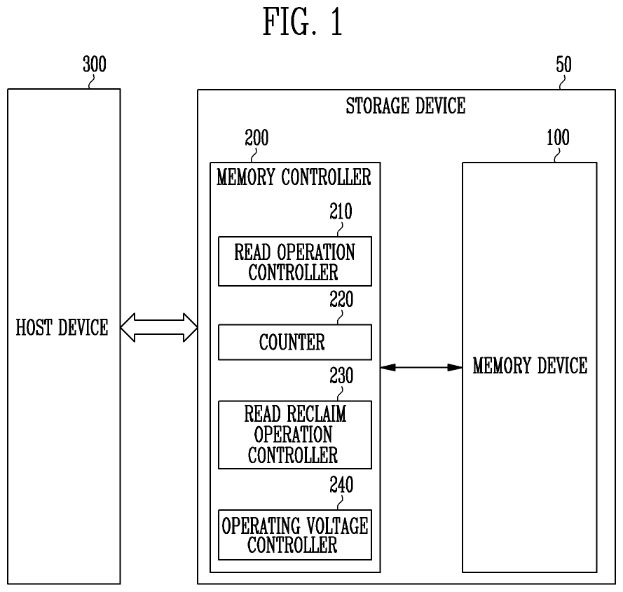

FIG. 1 is a diagram illustrating a storage device 50 according to an embodiment of the present disclosure.

Referring to FIG. 1, the storage device 50 may include a memory device 100 and a memory controller 200 which controls the memory device 100. The storage device 50 may store data under the control of a host device 300, such as a mobile phone, a smartphone, an MP3 player, a laptop computer, a desktop computer, a game console, a television (TV), a tablet PC, or an in-vehicle infotainment system.

The storage device 50 may be implemented as one of various types of storage devices, for example, a solid state disk (SSD), a multimedia card such as an MMC, an embedded MMC (eMMC), a reduced size MMC (RS-MMC), or a micro-MMC, a secure digital card such as an SD, a mini-SD, or a micro-SD, a universal serial bus (USB) storage device, a universal flash storage (UFS) device, a personal computer memory card international association (PCMCIA) card-type storage device, a peripheral component interconnection (PCI)-card type storage device, a PCI express (PCI-e or PCIe) card-type storage device, a compact flash (CF) card, a smart media card, and a memory stick depending on a method for communication with the host device 300.

The storage device 50 may be manufactured in one of various types of package forms. For example, the storage device 50 may be manufactured in one of various types of package forms, such as package on package (POP), system in package (SIP), system on chip (SOC), multi-chip package (MCP), chip on board (COB), wafer-level fabricated package (WFP), and wafer-level stack package (WSP).

The memory device 100 may store data. The memory device 100 may be operated in response to the control of the memory controller 200. The memory device 100 may include a plurality of memory blocks which store data. Each memory block may include a plurality of memory cells.

In an embodiment, the memory device 100 may be a nonvolatile memory in which data is retained even when power is interrupted. In the present specification, for convenience, description will be made based on that the memory device 100 is a NAND flash memory.

In an embodiment, the memory device 100 may receive a command and an address from the memory controller 200. The memory device 100 may perform an operation indicated by the command on an area selected by the address. For example, the memory device 100 may perform a write operation (or a program operation), a read operation, and an erase operation.

The memory controller 200 may control the overall operation of the storage device 50.

When power is applied to the storage device 50, the memory controller 200 may run firmware (FW). When the memory device 100 is a flash memory device, the firmware may include a host interface layer (HIL) which controls communication with the host device 300, a flash translation layer (FTL) which controls communication between the host device 300 and the memory device 100, and a flash interface layer (FIL) which controls communication with the memory device 100.

In an embodiment, the memory controller 200 may receive data and a logical block address (LBA) from the host device 300, and may translate the logical block address (LBA) into a physical block address (PBA) indicating the address of memory cells which are included in the memory device 100 and in which the data is to be stored. In the present specification, a logical block address and a “logical address” may be used interchangeably with each other. In the present specification, a physical block address and a “physical address” may be used interchangeably with each other.

In an embodiment, the memory controller 200 may provide the memory device 100 with a command, an address, or data corresponding to a program operation, a read operation or an erase operation so that the corresponding operation is performed in response to a request from the host device 300.

In an embodiment, the memory controller 200 may independently generate a command, an address, and data regardless of whether the request of the host device 300 is received, and may transmit them to the memory device 100. For example, the memory controller 200 may provide the memory device 100 with commands, addresses, and data which are required for performing program operations and read operations associated with performance of internal operations such as a wear leveling operation, a read reclaim operation, and a garbage collection operation.

In an embodiment, the memory controller 200 may include a read operation controller 210, a counter 220, a read reclaim operation controller 230, and an operating voltage controller 240.

The read operation controller 210 may control the read operation of the memory device 100. For example, the read operation controller 210 may provide the memory device 100 with a read command indicating a read operation and an address indicating a position at which data to be read is stored.

The counter 220 may count the number of read operations (read operation count) performed on the memory device 100. For example, the counter 220 may count the number of read operations performed on each of the plurality of memory blocks included in the memory device 100.

Also, the counter 220 may count time. For example, the time counted by the counter 220 may be used to determine whether the counted time has reached a preset time period.

The read reclaim operation controller 230 may control a read reclaim operation on a memory block.

In an embodiment, when the number of read operations performed on a target memory block reaches a preset number, the read reclaim operation controller 230 may determine whether a read reclaim operation is to be performed on the target memory block. For example, when the number of read operations performed on the target memory block reaches the preset number, the read reclaim operation controller 230 may perform a fall bit check operation on the target memory block. The fall bit check operation may be performed such that, when the number of fall bits contained in data read from the target memory block is greater than a reference value, the read reclaim operation controller 230 may move data in the target memory block to another memory block. On the other hand, when the number of fall bits contained in the data read through the test read operation is less than or equal to the reference value, the read reclaim operation controller 230 may not perform a read reclaim operation. Further, either when the number of read operations performed on the target memory block reaches again the preset number or at preset time periods, the read reclaim operation controller 230 may determine whether a read reclaim operation is to be performed on the target memory block.

The operating voltage controller 240 may control operating voltages that are used in the read operation.

In an embodiment, during the read operation, the operating voltage controller 240 may control a pass voltage to be applied to an unselected word line. For example, when the number of read operations performed on the target memory block is less than or equal to the preset number, the operating voltage controller 240 may control the memory device 100 to apply a pass voltage less than a default pass voltage to an unselected word line connected to the target memory block during the read operation on the target memory block. When the number of read operations performed on the target memory block is greater than the preset number, the operating voltage controller 240 may control the memory device 100 to apply the default pass voltage to the unselected word line connected to the target memory block during the read operation on the target memory block.

In an embodiment, the operating voltage controller 240 may adjust the magnitude of the pass voltage based on a time point at which it is determined whether a read reclaim operation is to be performed. For example, the operating voltage controller 240 may control the memory device 100 to adjust the magnitude of the pass voltage to be applied to at least one unselected word line during the read operation on the target memory block depending on whether the number of read operations performed on the target memory block reaches the preset number. In detail, the operating voltage controller 240 may control the memory device 100 so that the magnitude of the pass voltage applied to the unselected word line decreases from the magnitude of the default pass voltage during the read operation on the target memory block before the number of read operations performed on the target memory block reaches the preset number. Furthermore, the operating voltage controller 240 may control the memory device 100 so that the magnitude of the pass voltage applied to the unselected word line increases to the magnitude of the default pass voltage during the read operation on the target memory block when the number of read operations performed on the target memory block reaches the preset number.

In an embodiment, the memory device 100 may set the magnitude of the pass voltage under the control of the operating voltage controller 240. Also, when the read command is received from the read operation controller 210, the memory device 100 may perform a read operation based on the magnitude of the set pass voltage.

In the above-described embodiment, although the magnitude of the pass voltage is described as being controlled by the memory controller 200, the embodiments of the present disclosure are not limited thereto. For example, the memory device 100 may count the number of read operations performed on each memory block, and may autonomously adjust the magnitude of the pass voltage depending on whether the counted number of read operations is low or high.

The host device 300 may communicate with the storage device 50 using at least one of various communication standards or interfaces such as universal serial bus (USB), serial AT attachment (SATA), serial Attached SCSI (SAS), high speed interchip (HSIC), small computer system interface (SCSI), peripheral component interconnection (PCI), PCI express (PCIe), nonvolatile memory express (NVMe), universal flash storage (UFS), secure digital (SD), multimedia card (MMC), embedded MMC (eMMC), dual in-line memory module (DIMM), registered DIMM (RDIMM), and load reduced DIMM (LRDIMM) communication methods.

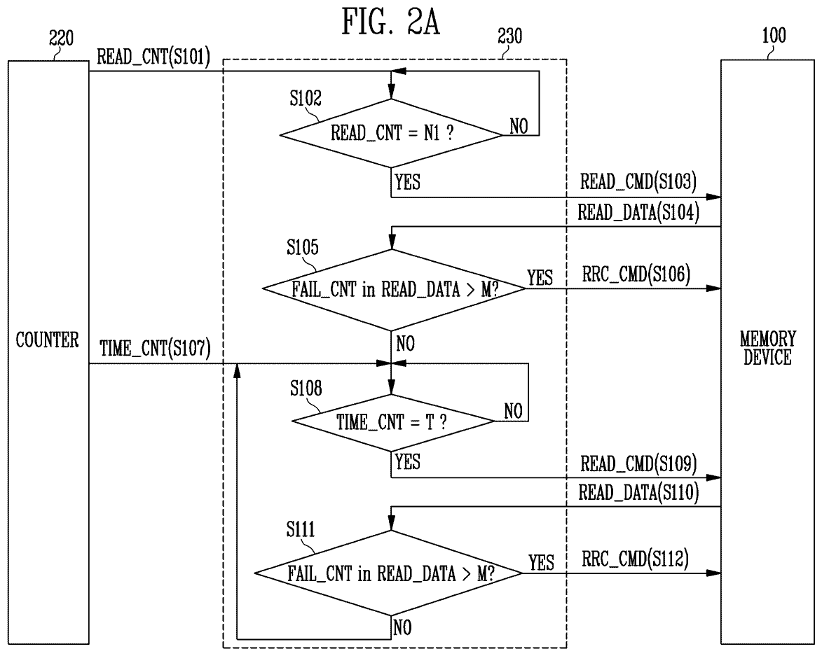

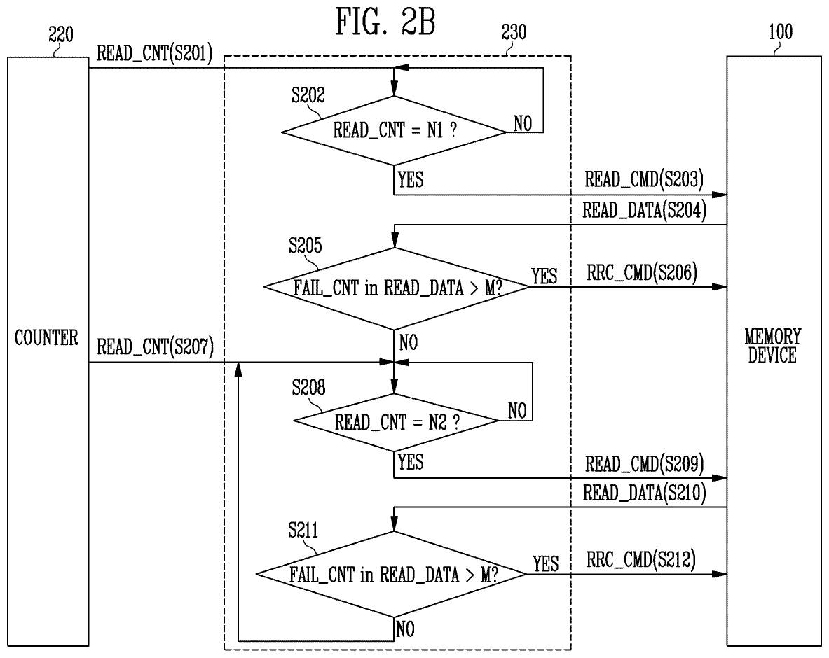

FIGS. 2A and 2B are diagrams illustrating a read claim operation according to an embodiment of the present disclosure.

In detail, FIG. 2A is a diagram illustrating an embodiment in which, after an execution condition for a read reclaim operation is first determined, the execution condition for the read reclaim operation is determined again at preset time periods.

Referring to FIG. 2A, at S101, the read reclaim operation controller 230 of FIG. 1 may receive, from the counter 220, the number of read operations (read operation count) READ_CNT performed on a target memory block. The number of read operations READ_CNT may refer to the number of read operations performed after data was initially stored in the target memory block or since data was stored after an erase operation.

At S102, the read reclaim operation controller 230 may determine whether the number of read operations READ_CNT reaches a preset first number (first count) N1. When it is determined that the number of read operations READ_CNT does not reach the first number N1 (S102, NO), the read reclaim operation controller 230 may check the number of read operations READ_CNT until the number of read operations READ_CNT reaches the first number N1. When it is determined that the number of read operations READ_CNT reaches the first number N1 (S102, YES), the read reclaim operation controller 230 may perform a fall bit check operation of determining whether a read reclaim operation is to be performed.

For example, at S103, the read reclaim operation controller 230 may provide the memory device 100 with a read command READ_CMD for instructing data in the target memory block to be read.

At S104, the memory device 100 may provide read data READ_DATA, read from the target memory block, to the read reclaim operation controller 230.

At S105, the read reclaim operation controller 230 may determine whether the number of fail bits FAIL_CNT contained in the read data READ_DATA is greater than a reference value M.

When it is determined that the number of fail bits FAIL_CNT contained in the read data READ_DATA is greater than the reference value M (S105, YES), at S106, the read reclaim operation controller 230 may provide a command RRC_CMD for controlling the read reclaim operation to the memory device 100.

When it is determined that the number of fail bits FAIL_CNT contained in the read data READ_DATA is not greater than the reference value M (S105, NO), the read reclaim operation controller 230 may not perform a read reclaim operation. Thereafter, the read reclaim operation controller 230 may determine whether a read reclaim operation is to be performed, at preset time periods.

For example, at S107, the read reclaim operation controller 230 may receive time information TIME_CNT obtained by counting time from the counter 220.

At S108, the read reclaim operation controller 230 may determine whether the counted time information TIME_CNT reaches a reference value T. When it is determined that the counted time information TIME_CNT does not reach the reference value T (S108, NO), the read reclaim operation controller 230 may check the time information TIME_CNT until the counted time information TIME_CNT reaches the reference value T. When it is determined that the counted time information TIME_CNT reaches the reference value T (S108, YES), the read reclaim operation controller 230 may determine that the time has reached a preset time period, and may then perform a fall bit check operation of determining whether a read reclaim operation is to be performed.

For example, at S109, the read reclaim operation controller 230 may provide the memory device 100 with a read command READ_CMD for instructing data in the target memory block to be read.

At S110, the memory device 100 may provide read data READ_DATA, read from the target memory block, to the read reclaim operation controller 230.

At S111, the read reclaim operation controller 230 may determine whether the number of fail bits FAIL_CNT contained in the read data READ_DATA is greater than a reference value M.

When it is determined that the number of fail bits FAIL_CNT contained in the read data READ_DATA is greater than the reference value M (S111, YES), the read reclaim operation controller 230 may provide a command RRC_CMD for controlling the read reclaim operation to the memory device 100 at step S112.

When it is determined that the number of fail bits FAIL_CNT contained in the read data READ_DATA is not greater than the reference value M (S111, NO), the read reclaim operation controller 230 may determine that a read reclaim operation is not to be performed. Thereafter, the read reclaim operation controller 230 may determine whether time has reached the preset time period by repeating S107 and S108, and may determine again whether a read reclaim operation is to be performed at S109 to S111.

FIG. 2B is a diagram illustrating an embodiment in which, after an execution condition for a read reclaim operation is initially determined, the execution condition for the read reclaim operation is determined again based on the number of read operations performed on a target memory block.

Referring to FIG. 2B, at S201, the read reclaim operation controller 230 may receive the number of read operations (read operation count) READ_CNT performed on a target memory block from the counter 220. The number of read operations READ_CNT may refer to the number of read operations performed after data was initially stored in the target memory block or since data was stored after an erase operation.

At S202, the read reclaim operation controller 230 may determine whether the number of read operations READ_CNT reaches a preset first number N1. When it is determined that the number of read operations READ_CNT does not reach the first number N1 (S202, NO), the read reclaim operation controller 230 may check the number of read operations READ_CNT until the number of read operations READ_CNT reaches the first number N1. When it is determined that the number of read operations READ_CNT reaches the first number N1 (S202, YES), the read reclaim operation controller 230 may perform a fall bit check operation of determining whether a read reclaim operation is to be performed.

For example, at S203, the read reclaim operation controller 230 may provide the memory device 100 with a read command READ_CMD for instructing data in the target memory block to be read.

At S204, the memory device 100 may provide read data READ_DATA, read from the target memory block, to the read reclaim operation controller 230.

At S205, the read reclaim operation controller 230 may determine whether the number of fail bits FAIL_CNT contained in the read data READ_DATA is greater than a reference value M.

When it is determined that the number of fail bits FAIL_CNT contained in the read data READ_DATA is greater than the reference value M (S205, YES), at S206, the read reclaim operation controller 230 may provide a command RRC_CMD for controlling the read reclaim operation to the memory device 100.

When it is determined that the number of fail bits FAIL_CNT contained in the read data READ_DATA is not greater than the reference value M (S205, NO), the read reclaim operation controller 230 may not perform a read reclaim operation. Thereafter, the read reclaim operation controller 230 may determine whether a read reclaim operation is to be performed based on the number of read operations performed on the target memory block.

For example, at S207, the read reclaim operation controller 230 may receive the number of read operations READ_CNT performed on a target memory block from the counter 220. The number of read operations READ_CNT may refer to the number of read operations READ_CNT performed on the target memory block after the fall bit check operation.

At S208, the read reclaim operation controller 230 may determine whether the number of read operations READ_CNT reaches a preset second number (second count) N2. The second number N2 may be identical to or different from the first number N1. When it is determined that the number of read operations READ_CNT does not reach the second number N2 (S208, NO), the read reclaim operation controller 230 may check the number of read operations READ_CNT until the number of read operations READ_CNT reaches the second number N2. When it is determined that the number of read operations READ_CNT reaches the second number N2 (S208, YES), the read reclaim operation controller 230 may perform a fall bit check operation of determining whether a read reclaim operation is to be performed.

For example, at S209, the read reclaim operation controller 230 may provide the memory device 100 with a read command READ_CMD for instructing data in the target memory block to be read.

At S210, the memory device 100 may provide read data READ_DATA, read from the target memory block, to the read reclaim operation controller 230.

At S211, the read reclaim operation controller 230 may determine whether the number of fail bits FAIL_CNT contained in the read data READ_DATA is greater than a reference value M.

When it is determined that the number of fail bits FAIL_CNT contained in the read data READ_DATA is greater than the reference value M (S211, YES), at S212, the read reclaim operation controller 230 may provide a command RRC_CMD for controlling the read reclaim operation to the memory device 100.

When it is determined that the number of fail bits FAIL_CNT contained in the read data READ_DATA is not greater than the reference value M (S211, NO), the read reclaim operation controller 230 may determine that a read reclaim operation is not to be performed. Thereafter, the read reclaim operation controller 230 may determine whether the number of read operations, performed on the target memory block after the fall bit check operation, reaches the second number by repeating S207 and S208, and may determine again whether a read reclaim operation is to be performed at S209 to S211.

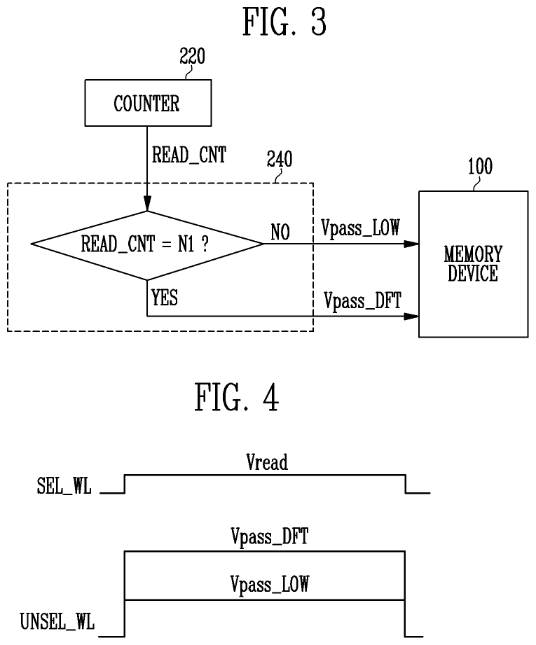

FIG. 3 is a diagram illustrating determining a pass voltage to be applied to an unselected word line according to an embodiment of the present disclosure.

In an embodiment, the memory controller 200 may control the memory device 100 so that, before the number of read operations performed on a target memory block reaches a first number, the magnitude of a pass voltage decreases from the magnitude of a default pass voltage.

In an embodiment, the memory controller 200 may control the memory device 100 so that, when the number of read operations performed on the target memory block reaches the first number, the magnitude of the decreased pass voltage increases to the magnitude of the default pass voltage.

Referring to FIG. 3, the operating voltage controller 240 may receive, from the counter 220, the number of read operations READ_CNT performed on the target memory block. The number of read operations may refer to the number of read operations performed after data was initially stored in the target memory block or since data was stored after an erase operation.

When it is determined that the number of read operations READ_CNT performed on the target memory block does not reach the first number N1 (NO), the operating voltage controller 240 may provide, to the memory device 100, information about a pass voltage Vpass_LOW less than the default pass voltage Vpass_DFT. Accordingly, the memory device 100 may set the pass voltage so that the magnitude of the pass voltage decreases from the magnitude of the default pass voltage Vpass_DFT, and may perform a read operation using the pass voltage Vpass_LOW having the decreased magnitude.

When it is determined that the number of read operations READ_CNT performed on the target memory block reaches the first number N1 (YES), the operating voltage controller 240 may provide, to the memory device 100, information about the default pass voltage Vpass_DFT. Accordingly, the memory device 100 may set the pass voltage so that the decreased magnitude of the pass voltage Vpass_LOW increases to the magnitude of the default pass voltage Vpass_DFT, and may perform a read operation using the default pass voltage Vpass_DFT.

FIG. 4 is a diagram illustrating a pass voltage applied to an unselected word line according to an embodiment of the present disclosure. In FIG. 4, only a period in which a read voltage is applied to a selected word line during a read operation is illustrated for convenience, and a word line rising period before the read voltage is applied, an equalizing period after the read voltage is applied, etc. are omitted.

In detail, FIG. 4 is a diagram for describing an embodiment in which the pass voltage determined in FIG. 3 is applied to an unselected word line UNSEL_WL.

Referring to FIG. 4, during the read operation, the read voltage Vread may be applied to a selected word line SEL_WL and the pass voltage may be applied to the unselected word line UNSEL_WL.

In an embodiment, before the number of read operations READ_CNT performed on a target memory block reaches a first number, a pass voltage Vpass_LOW having a magnitude decreased from the magnitude of a default pass voltage Vpass_DFT may be applied to the unselected word line UNSEL_WL.

In an embodiment, the decreased magnitude of the pass voltage Vpass_LOW may be greater than that of the read voltage Vread applied to the selected word line SEL_WL.

In an embodiment, when the number of read operations READ_CNT performed on the target memory block reaches the first number, the default pass voltage Vpass_DFT may be applied to the unselected word line UNSEL_WL.

Consequently, before a time point at which it is first determined whether a read reclaim operation is to be performed, the pass voltage Vpass_LOW less than the default pass voltage Vpass_DFT may be applied to the unselected word line, and the decreased pass voltage Vpass_LOW may be changed to the default pass voltage Vpass_DFT at the time point at which it is first determined whether the read reclaim operation is to be performed.

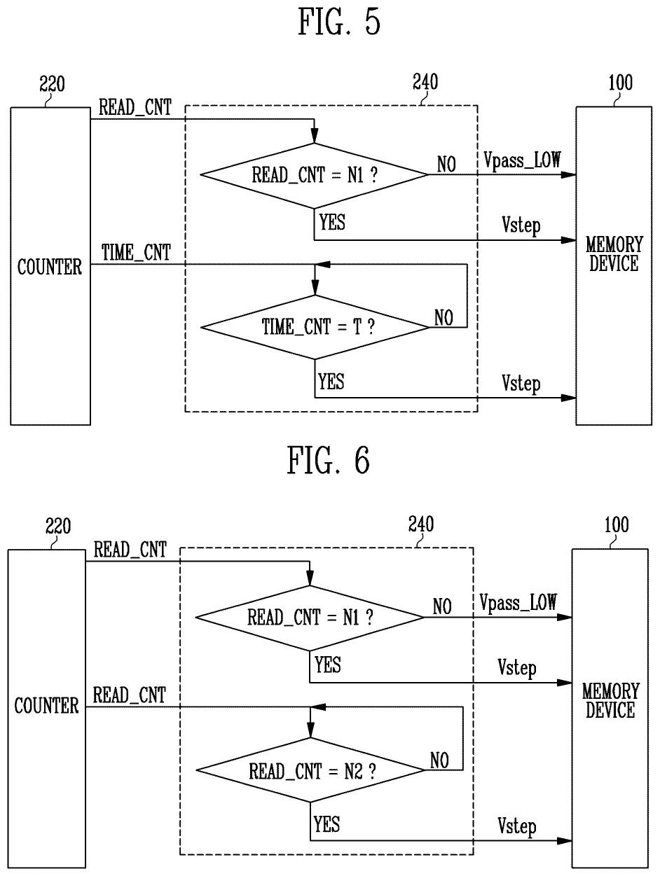

FIG. 5 is a diagram illustrating determining a pass voltage to be applied to an unselected word line according to an embodiment of the present disclosure. FIG. 5 is a diagram for describing an embodiment in which a pass voltage is determined when the read reclaim operation, described above with reference to FIG. 2A, is performed.

In an embodiment, the memory controller 200 may control the memory device 100 so that a decreased magnitude of a pass voltage is increased by a step magnitude to reach the magnitude of a default pass voltage at the time point at which the number of read operations performed on a target memory block reaches a first number and at preset time periods.

Referring to FIG. 5, the operating voltage controller 240 may receive, from the counter 220, the number of read operations READ_CNT performed on the target memory block. The number of read operations may refer to the number of read operations performed after data was initially stored in the target memory block or since data was stored after an erase operation.

When it is determined that the number of read operations READ_CNT performed on the target memory block does not reach the first number N1 (NO), the operating voltage controller 240 may provide, to the memory device 100, information about a pass voltage Vpass_LOW less than the default pass voltage Vpass_DFT. Accordingly, the memory device 100 may set the pass voltage so that the magnitude of the pass voltage decreases from the magnitude of the default pass voltage Vpass_DFT, and may perform a read operation using the pass voltage Vpass_LOW having the decreased magnitude.

When it is determined that the number of read operations READ_CNT performed on the target memory block reaches the first number N1 (YES), the operating voltage controller 240 may provide, to the memory device 100, information about a step voltage Vstep having a step magnitude. Accordingly, the memory device 100 may set the pass voltage so that the decreased magnitude of the pass voltage Vpass_LOW is increased by the magnitude of the step voltage, and may perform a read operation using the pass voltage having the set magnitude.

Also, the operating voltage controller 240 may receive counted time information TIME_CNT from the counter 220 after the number of read operations READ_CNT performed on the target memory block has reached the first number N1. When the counted time information TIME_CNT reaches a reference value T and then it is determined that the time reaches a preset time period (YES), the operating voltage controller 240 may provide, to the memory device 100, information about the step voltage Vstep having a step magnitude. That is, after the number of read operations READ_CNT performed on the target memory block has reached the first number N1, the operating voltage controller 240 may provide information about the step voltage Vstep to the memory device 100 at preset time periods. Accordingly, the memory device 100 may set the pass voltage so that the magnitude of the pass voltage is increased from a previous pass voltage by the magnitude of the step voltage at preset time periods, and may perform a read operation using the pass voltage having the set magnitude.

FIG. 6 is a diagram illustrating a pass voltage applied to an unselected word line according to an embodiment of the present disclosure. FIG. 6 is a diagram for describing an embodiment in which a pass voltage is determined when the read reclaim operation, described above with reference to FIG. 2B, is performed.

In an embodiment, the memory controller 200 may control the memory device 100 so that the decreased magnitude of the pass voltage is increased by a step magnitude to reach the magnitude of the default pass voltage at each time point at which the number of read operations performed on the target memory block reaches a first number and at which the number of read operations reaches a second number.

Referring to FIG. 6, the operating voltage controller 240 may receive, from the counter 220, the number of read operations READ_CNT performed on the target memory block. The number of read operations may refer to the number of read operations performed after data was initially stored in the target memory block or since data was stored after an erase operation.

When it is determined that the number of read operations READ_CNT performed on the target memory block does not reach the first number N1 (NO), the operating voltage controller 240 may provide, to the memory device 100, information about a pass voltage Vpass_LOW less than the default pass voltage Vpass_DFT. Accordingly, the memory device 100 may set the pass voltage so that the magnitude of the pass voltage decreases from the magnitude of the default pass voltage Vpass_DFT, and may perform a read operation using the pass voltage Vpass_LOW having the decreased magnitude.

When it is determined that the number of read operations READ_CNT performed on the target memory block reaches the first number N1 (YES), the operating voltage controller 240 may provide, to the memory device 100, information about a step voltage Vstep having a step magnitude. Accordingly, the memory device 100 may set the pass voltage so that the decreased magnitude of the pass voltage Vpass_LOW is increased by the magnitude of the step voltage, and may perform a read operation using the pass voltage having the set magnitude.

Furthermore, the operating voltage controller 240 may receive, from the counter 220, the number of read operations performed on the target memory block after the number of read operations READ_CNT has reached the first number N1. When it is determined that the number of read operations READ_CNT performed on the target memory block reaches the second number N2 (YES), the operating voltage controller 240 may provide, to the memory device 100, information about the step voltage Vstep having the step magnitude. That is, the operating voltage controller 240 may provide the information about the step voltage Vstep to the memory device 100 whenever a time point at which it is determined whether a read reclaim operation is to be performed is reached. Accordingly, the memory device 100 may set the pass voltage so that the decreased magnitude of the pass voltage Vpass_LOW is increased by the magnitude of the step voltage, and may perform a read operation using the pass voltage having the set magnitude.

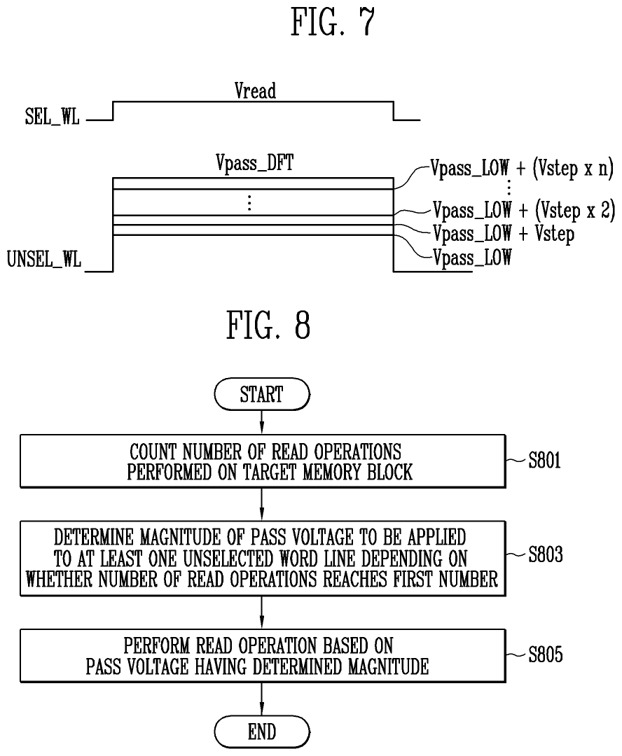

FIG. 7 is a diagram illustrating a pass voltage applied to an unselected word line according to an embodiment of the present disclosure. In FIG. 7, only a period in which a read voltage is applied to a selected word line during a read operation is illustrated for convenience, and a word line rising period before the read voltage is applied, an equalizing period after the read voltage is applied, etc. are omitted.

In detail, FIG. 7 is a diagram for describing an embodiment in which the pass voltage determined in FIG. 5 or 6 is applied to an unselected word line UNSEL_WL. However, for convenience, an embodiment in which the pass voltage is stepwise increased at a time point at which the number of read operations reaches a first number and at preset time periods, as shown in FIG. 5, will be described below. The following description may be equally applied to the embodiment in which the pass voltage is stepwise increased at each time point at which the number of read operations reaches a first number and a second number, as shown in FIG. 6.

Referring to FIG. 7, the read voltage Vread may be applied to a selected word line SEL_WL and the pass voltage may be applied to the unselected word line UNSEL_WL during the read operation.

In an embodiment, before the number of read operations READ_CNT performed on a target memory block reaches a first number, a pass voltage Vpass_LOW having a magnitude decreased from the magnitude of a default pass voltage Vpass_DFT may be applied to the unselected word line UNSEL_WL.

In an embodiment, the decreased magnitude of the pass voltage Vpass_LOW may be greater than that of the read voltage Vread applied to the selected word line SEL_WL.

In an embodiment, when the number of read operations READ_CNT performed on the target memory block reaches the first number, a pass voltage Vpass_LOW+Vstep increased from the previously applied pass voltage Vpass_LOW by a step voltage Vstep may be applied to the unselected word line UNSEL_WL.

In an embodiment, when a preset period is reached after the number of read operations READ_CNT performed on the target memory block has reached the first number, a pass voltage Vpass_LOW+(Vstep×2) increased from the previously applied pass voltage Vpass_LOW+Vstep by the step voltage Vstep may be applied to the unselected word line UNSEL_WL. When the preset period is repeated, the default pass voltage Vpass_DFT may be finally applied to the unselected word line UNSEL_WL.

Consequently, before a time point at which it is first determined whether a read reclaim operation is to be performed, the pass voltage Vpass_LOW less than the default pass voltage Vpass_DFT may be applied to the unselected word line UNSEL_WL, and at each time point at which it is determined whether a read reclaim operation is to be performed, the decreased pass voltage Vpass_LOW may be stepwise increased to finally reach the default pass voltage Vpass_DFT.

FIG. 8 is a flowchart illustrating a method of operating a storage device according to an embodiment of the present disclosure. The method illustrated in FIG. 8 may be performed by, for example, the storage device 50 illustrated in FIG. 1.

Referring to FIG. 8, at S801, the storage device 50 may count the number of read operations performed on a target memory block among a plurality of memory blocks.

At S803, the storage device 50 may determine the magnitude of a pass voltage to be applied to at least one unselected word line among a plurality of word lines during a read operation on the target memory block depending on whether the number of read operations performed on the target memory block reaches a first number.

For example, the storage device 50 may decrease the magnitude of the pass voltage from the magnitude of the default pass voltage before the number of read operations performed on the target memory block reaches the first number. The decreased magnitude of the pass voltage may be greater than the magnitude of the read voltage applied to a selected word line among the plurality of word lines during the read operation.

The storage device 50 may increase the decreased magnitude of the pass voltage to the magnitude of the default pass voltage when the number of read operations performed on the target memory block reaches the first number.

The storage device 50 may stepwise increase the decreased magnitude of the pass voltage up to the magnitude of the default pass voltage at preset time periods from a time point at which the number of read operations performed on the target memory block reaches the first number.

The storage device 50 may increase the decreased magnitude of the pass voltage by a step magnitude when the number of read operations performed on the target memory block reaches the first number. Further, the storage device 50 may increase again the increased magnitude of the pass voltage by the step magnitude when the number of read operations performed on the target memory block reaches a second number after the number of read operations performed on the target memory block has reached the first number.

At S805, the storage device 50 may perform a read operation on the target memory block based on the pass voltage having the determined magnitude.

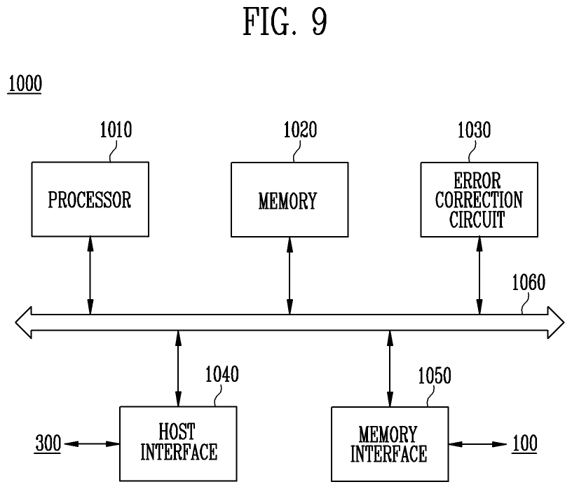

FIG. 9 is a diagram illustrating a memory controller 1000 according to an embodiment of the present disclosure. The memory controller 1000 may refer to the memory controller 200 illustrated in FIG. 1.

Referring to FIG. 9, the memory controller 1000 may include a processor 1010, a memory 1020, an error correction circuit 1030, a host interface 1040, a memory interface 1050, and a communication bus 1060. In the memory controller 1000, the processor 1010, the memory 1020, the error correction circuit 1030, the host interface 1040, and the memory interface 1050 may communicate with each other through the communication bus 1060.

The processor 1010 may execute firmware, code or one or more instructions, which include various types of information required for the operation of the memory controller 1000. In an embodiment, the read operation controller 210, the counter 220, the read reclaim operation controller 230, and the operating voltage controller 240 of FIG. 1 may be implemented using one or more components stored in the processor 1010.

In an embodiment, the processor 1010 may control the memory device 100 to adjust the magnitude of a pass voltage to be applied to at least one unselected word line during the read operation on the target memory block depending on whether the number of read operations performed on the target memory block reaches a preset number.

For example, the processor 1010 may count the number of read operations performed on the target memory block. The processor 1010 may control the memory device 100 so that, before the number of read operations performed on the target memory block reaches the preset number, the magnitude of the pass voltage decreases from the magnitude of a default pass voltage. When the number of read operations performed on the target memory block reaches the preset number, the processor 1010 may control the memory device 100 so that, the decreased magnitude of the pass voltage increases to the magnitude of the default pass voltage.

The memory 1020 may be used as a buffer memory, a cache memory, a working memory, or the like.

Further, the memory 1020 may store the firmware, code or one or more instructions including various types of information required for the operation of the memory controller 1000.

The error correction circuit 1030 may perform error correction when data is stored in the memory device 100 or when data is read from the memory device 100. For example, the error correction circuit 1030 may perform error correcting code (ECC) encoding based on data to be written to the memory device 100. The encoded data may be transferred to the memory device 100. The error correction circuit 1030 may perform error correcting code decoding on data received from the memory device 100.

The memory controller 1000 may communicate with an external device (e.g., a host device 300, an application processor or the like) through the host interface 1040.

The memory controller 1000 may communicate with the memory device 100 through the memory interface 1050. The memory controller 1000 may transmit a command, an address, a control signal, or the like to the memory device 100 and receive data from the memory device 100, through the memory interface 1050.

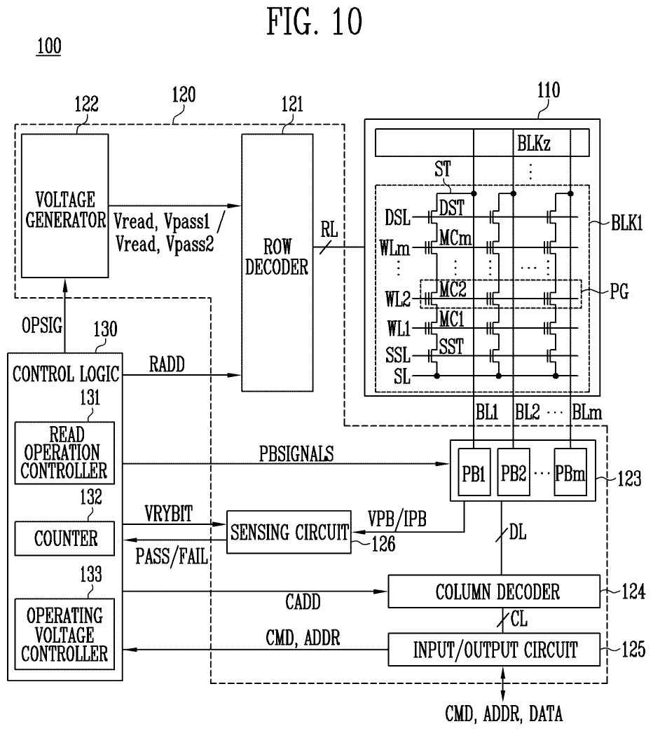

FIG. 10 is a diagram illustrating a memory device according to an embodiment of the present disclosure. The memory device illustrated in FIG. 10 may refer to the memory device 100 illustrated in FIG. 1.

Referring to FIG. 10, the memory device 100 may include a memory cell array 110, a peripheral circuit 120, and a control logic 130.

The memory cell array 110 includes a plurality of memory blocks BLK1 to BLKz.

The plurality of memory blocks BLK1 to BLKz are connected to a row decoder 121 through row lines RL. The row lines RL may include at least one source select line SSL, a plurality of word lines WL1 to WLm, and at least one drain select line DSL. The source select line SSL may be connected to a source select transistor SST, and the drain select line DSL may be connected to a drain select transistor DST. The source select transistor SST may be controlled through the source select line SSL, and the drain select transistor DST may be controlled through the drain select line DSL.

Each of the memory blocks BLK1 to BLKz may include a plurality of memory cells MC1 to MCm. The plurality of memory cells MC1 to MCm may be connected to a page buffer circuit 123 through a plurality of bit lines BL1 to BLm.

Each of the plurality of memory blocks BLK1 to BLKz may include a plurality of memory cell strings ST connected between the bit lines BL1 to BLm and a common source line CSL. Each of the memory cell strings ST may include at least one source select transistor SST, a plurality of memory cells MC1 to MCm, and at least one drain select transistor DST which are connected in series to each other between the common source line CSL and a corresponding one of the bit lines BL1 to BLm. The plurality of memory cells MC1 to MCm may be connected between the common source line CSL and one bit line BL1. The source select transistors SST may be connected between the common source line CSL and the plurality of memory cells MC1 to MCm. The drain select transistors DST may be connected between the bit line BL1 and the plurality of memory cells MC1 to MCm.

Each of the plurality of memory cells MC1 to MCm may be connected to one of the plurality of word lines WL1 to WLm. Memory cells connected to the same word line may be defined as one page (PG). Each of the memory cells MC1 to MCm may store a plurality of data bits.

The peripheral circuit 120 may perform a program operation, a read operation, or an erase operation on a selected area of the memory cell array 110 under the control of the control logic 130.

The peripheral circuit 120 may include the row decoder 121, a voltage generator 122, the page buffer circuit 123, a column decoder 124, an input and output (input/output) circuit 125, and a sensing circuit 126.

The row decoder 121 may decode a row address RADD received from the control logic 130. The row decoder 121 selects at least one of the memory blocks BLK1 to BLKz according to the decoded address. Further, the row decoder 121 may select at least one word line of the memory block selected according to the decoded address. The row decoder 121 may apply voltages Vop generated by the voltage generator 122 to the selected word line.

The voltage generator 122 may generate a plurality of voltages using an external supply voltage provided to the memory device 100. In detail, the voltage generator 122 may generate various operating voltages Vop that are used for program, read, and erase operations in response to an operation signal OPSIG. The generated operating voltages Vop may be supplied to the memory cell array 110 through the row decoder 121.

The page buffer circuit 123 may include a plurality of page buffers PB1 to PBm. The plurality of page buffers PB1 to PBm may temporarily store data received through the plurality of bit lines BL1 to BLm or sense the voltages or currents of the plurality of bit lines BL1 to BLm during a read or verify operation, in response to page buffer control signals PBSIGNALS.

The column decoder 124 may transfer data between the input/output circuit 125 and the page buffer circuit 123 in response to a column address CADD.

The input/output circuit 125 may transmit a command CMD and an address ADDR, received from a memory controller 200, to the control logic 130, or may exchange data DATA with the column decoder 124.

The sensing circuit 126 may determine whether a verify operation for a specific program state has passed with the application of a verify voltage.

In an embodiment, the sensing circuit 126 may perform a check operation of determining whether the verify operation has passed based on data sensed from the plurality of memory cells MC1 to MCm while a program voltage is applied to a word line.

During the verify operation, the sensing circuit 126 may generate a reference current in response to an enable bit signal VRYBIT, and may compare a sensing voltage VPB received from the page buffer group 123 with a reference voltage generated by the reference current and then output a pass signal PASS or a fail signal FAIL. During the verify operation, the sensing circuit 126 may generate a reference voltage in response to the enable bit signal VRYBIT, and may compare a sensing current IPB received from the page buffer group 123 with a reference current generated by the reference voltage and then output a pass signal PASS or a fail signal FAIL.

Also, the sensing circuit 126 may perform a fail bit check operation of determining whether a read reclaim operation is to be performed.

The control logic 130 may control the peripheral circuit 120 by outputting the operation signal OPSIG, the row address RADD, and the page buffer control signals PBSIGNALS in response to the command CMD and the address ADDR.

In an embodiment, the control logic 130 may include a read operation controller 131, a counter 132, and an operating voltage controller 133.

The read operation controller 131 may control a read operation.

The counter 132 may count the number of read operations performed on each of the plurality of memory blocks BLK1 to BLKz included in the memory device 100.

Further, the counter 132 may count time. For example, the time counted by the counter 132 may be used to determine whether the counted time has reached a preset time period.

Although the number of read operations and counted time information are obtained through the counter in FIG. 10, the number of read operations and the counted time information may be provided from the memory controller 200.

The operating voltage controller 133 may provide, to the voltage generator 122, the control signal OPSIG for controlling the operating voltages Vop used for the read operation.

In an embodiment, during the read operation on the target memory block, the operating voltage controller 133 may control the voltage generator 122 to adjust the magnitude of the pass voltage to be applied to at least one unselected word line depending on whether the number of read operations performed on the target memory block reaches the preset number. The preset number may be data related to a time point at which it is determined whether a read reclaim operation is to be performed.

In an embodiment, during the read operation on the target memory block, the operating voltage controller 133 may generate a first pass voltage Vpass1 before the number of read operations performed on the target memory block reaches the preset number. When the number of read operations performed on the target memory block reaches the preset number, during the read operation on the target memory block, the operating voltage controller 133 may control the voltage generator 122 to generate a second pass voltage Vpass2 greater than the first pass voltage Vpass1. The first pass voltage Vpass1 may be greater than the read voltage Vread.

In an embodiment, the read operation controller 131 may control the read operation based on the determined pass voltage.

For example, during the read operation on the target memory block, the row decoder 121 may apply the read voltage Vread to the selected word line and apply the first pass voltage Vpass1 to the unselected word line before the number of read operations performed on the target memory block under the control of the read operation controller 131 reaches a preset number. Furthermore, during the read operation on the target memory block, when the number of read operations performed on the target memory block reaches the preset number, the row decoder 121 may apply the read voltage Vread to the selected word line and apply a second pass voltage Vpass2 to the unselected word line under the control of the read operation controller 131.

That is, the memory device 100 may count the number of read operations performed on each memory block, and may autonomously adjust the magnitude of the pass voltage depending on whether the counted number of read operations is low or high.

According to the embodiments of the present disclosure, there are provided a storage device and a method of operating the storage device, which can improve reliability while enhancing initial performance.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical idea of this disclosure but to describe the technical idea of this disclosure, the scope of the technical idea of this disclosure is not limited by these embodiments. The protection scope of this disclosure should be interpreted by the claims below, and all technical ideas within the equivalent scope should be interpreted as being included in the scope of the rights of this disclosure. Furthermore, the embodiments may be combined to form additional embodiments.

What is claimed is:

1. A storage device comprising:
a memory device including a plurality of memory blocks connected to a plurality of word lines, respectively, and configured to perform a read operation on a target memory block among the plurality of memory blocks; and
a memory controller configured to control the memory device to adjust a pass voltage depending on whether a number of read operations performed on the target memory block reaches a first number, and apply the adjusted pass voltage to at least one unselected word line among the plurality of word lines.

2. The storage device according to claim 1, wherein the memory controller is configured to control the memory device so that, before the number of read operations reaches the first number, a magnitude of the pass voltage decreases from a magnitude of a default pass voltage.

3. The storage device according to claim 2, wherein the decreased magnitude of the pass voltage is greater than a magnitude of a read voltage applied to a selected word line among the plurality of word lines during the read operation.

4. The storage device according to claim 2, wherein the memory controller is configured to control the memory device so that, when the number of read operations reaches the first number, the decreased magnitude of the pass voltage increases to the magnitude of the default pass voltage.

5. The storage device according to claim 2, wherein the memory controller is configured to, when the number of read operations reaches the first number, determine whether a read reclaim operation is to be performed on the target memory block, determine that the read reclaim operation is not to be performed on the target memory block, and thereafter determine again whether the read reclaim operation is to be performed on the target memory block at preset time periods.

6. The storage device according to claim 5, wherein the memory controller is configured to control the memory device so that the decreased magnitude of the pass voltage is increased by a step magnitude to reach the magnitude of the default pass voltage at a time point at which the number of read operations reaches the first number and at the preset time periods.

7. The storage device according to claim 2, wherein the memory controller is configured to, when the number of read operations reaches the first number, determine whether a read reclaim operation is to be performed on the target memory block, determine that the read reclaim operation is not to be performed on the target memory block, and thereafter determine again whether the read reclaim operation is to be performed on the target memory block when the number of read operations reaches a second number.

8. The storage device according to claim 7, wherein the memory controller is configured to control the memory device so that the decreased magnitude of the pass voltage is increased by a step magnitude to reach the magnitude of the default pass voltage at each time point at which the number of read operations reaches the first number and at which the number of read operations reaches the second number.

9. A method of operating a storage device, which includes a plurality of memory blocks connected to a plurality of word lines, respectively, the method comprising:
counting a number of read operations performed on a target memory block among the plurality of memory blocks;
determining a magnitude of a pass voltage depending on whether the number of read operations reaches a first number; and
performing the read operation on the target memory block by applying the pass voltage having the determined magnitude to at least one unselected word line among the plurality of word lines.

10. The method according to claim 9, wherein the determining comprises:
before the number of read operations reaches the first number, decreasing the magnitude of the pass voltage from a magnitude of a default pass voltage.

11. The method according to claim 10, wherein the decreased magnitude of the pass voltage is greater than a magnitude of a read voltage applied to a selected word line among the plurality of word lines during the read operation.

12. The method according to claim 10, where the determining further comprises:
increasing the decreased magnitude of the pass voltage to the magnitude of the default pass voltage when the number of read operations reaches the first number.

13. The method according to claim 10, where the determining further comprises:
stepwise increasing the decreased magnitude of the pass voltage to the magnitude of the default pass voltage at preset time periods from a time point at which the number of read operations reaches the first number.

14. The method according to claim 10, where the determining further comprises:
increasing the decreased magnitude of the pass voltage by a step magnitude when the number of read operations reaches the first number; and
increasing again the increased magnitude of the pass voltage by the step magnitude when the number of read operations reaches a second number after the number of read operations has reached the first number.

15. A memory device comprising:
a plurality of memory blocks connected to a plurality of word lines, respectively;
a voltage generator configured to generate a pass voltage to be applied to at least one unselected word line among the plurality of word lines during a read operation on a target memory block among the plurality of memory blocks; and
a control circuit configured to control the voltage generator to adjust the pass voltage depending on whether a number of read operations performed on the target memory block reaches a preset number.

16. The memory device according to claim 15, wherein the control circuit is configured to control the voltage generator to generate a first pass voltage before the number of read operations reaches the preset number, and to generate a second pass voltage greater than the first pass voltage when the number of read operations reaches the preset number.

17. The memory device according to claim 15, wherein the voltage generator is further configured to generate a read voltage to be applied to a selected word line among the plurality of word lines during the read operation.

18. The memory device according to claim 17, wherein the first pass voltage is greater than the read voltage.
